(19) United States
(12) Patent Application Publication
(10) Pub. No.: US 2022/0061146 A1
(43) Pub. Date: Feb. 24, 2022

(54) SYSTEM AND METHOD FOR PLASMA-SURFACE-TREATMENT OF CYLINDRIC AND ANNULAR WORKPIECES USING ATMOSPHERIC-PRESSURE PLASMA GENERATOR

(71) Applicant: Chang Hoon LEE, Seoul (KR)

(72) Inventor: Chang Hoon LEE, Seoul (KR)

(21) Appl. No.: 17/519,519

(22) Filed: Nov. 4, 2021

Related U.S. Application Data
(63) Continuation of application No. PCT/KR2021/006452, filed on May 24, 2021.

(30) Foreign Application Priority Data
May 22, 2020 (KR) 10-2020-0061332
May 24, 2021 (KR) 10-2021-0066020

(51) Int. Cl. H05H 1/00; H05H 1/24

(52) U.S. Cl. CPC H05H 1/01; H05H 1/24

(57) ABSTRACT

A system for surface treatment of a cylindric workpiece using an atmospheric pressure plasma generator according to an embodiment of the present disclosure includes a rotary plasma generator including a nozzle from which plasma is discharged, and a body to and from which the nozzle is attached and detached, and a plasma beam guide tap attached to one side of the nozzle about a rotation axis of the nozzle, in which the plasma beam guide tap is configured to discharge a plasma beam to at least a portion of a side of the workpiece while a rotation axis of the rotary plasma generator is aligned with a central axis of the cylindric workpiece.

### CROSS-REFERENCE TO RELATED APPLICATIONS

The present application is a continuation of International Patent Application No. PCT/KR2021/006452, filed May 24, 2021, which is based upon and claims the benefit of priority to Korean Patent Applications No. 10-2021-0066020, filed on May 24, 2021 and 10-2020-0061332, filed on May 22, 2020. The disclosures of the above-listed applications are hereby incorporated by reference herein in their entirety.

### BACKGROUND OF THE INVENTION

### Field of Invention

The present disclosure relates to a system and a method for surface treatment of cylindric and annular workpieces using an atmospheric pressure plasma generator, and more specifically, to a system and a method for carrying out surface modification of mutually coupled cylindric and annular workpieces through the plasma treatment of an outer surface of the cylindric workpiece and plasma treatment of an inner surface of the annular workpiece.

### Description of Related Art

Plasma is an ionized gas of electrons, neutral particles, and the like, and it can react directly with the surface of other material or react by elastic collision. A plasma generator mainly includes a tube configured to generate plasma when compressed air is collided with high-frequency, high-voltage electric charges. In recent years, use of atmospheric pressure plasma devices in place of low pressure plasma has increased. The atmospheric pressure plasma device may be applied to various materials and substrates with low-temperature process, and since it does not require a vacuum container or a vacuum evacuation device, fast and economic treatment is provided. In addition, with a deposition method employing the atmospheric pressure plasma, a good adhesion and low deposition temperature are provided, and thus, the method is used in a relatively wide area of industries by utilizing the advantages such as reduced deformation or denaturation that would accompany the high temperature heating in the related surface treatment process, semiconductor process, and display process.

In general, a plasma generator for use in a plasma-surface-treatment system is configured such that, for treating a surface of a planar workpiece, the workpiece or the plasma generator is moved along a straight line or moved linearly while the target surface of the workpiece is treated. For the surface treatment of a cylindric workpiece, the plasma generator may be held in a fixed state while the workpiece is rotated so that the outer surface of the workpiece can be uniformly treated. In addition, in the case of an annular workpiece, the plasma generator may be moved into the workpiece and rotated in that state so that the inner surface of the annular workpiece can be uniformly treated. Meanwhile, the related plasma-surface-treatment system has a problem that the plasma generator has a limited size or movement range, which makes it difficult to apply the same when the size of the cylindrical or annular workpiece is small or when it is necessary to surface-treat a local area.

### BRIEF SUMMARY OF THE INVENTION

The present disclosure has been made to overcome the problem mentioned above, and it is an object of the present disclosure to provide a system for surface treatment of a cylindric workpiece, including a tap structure for controlling a spraying direction of a plasma beam emitted from a nozzle of a rotary plasma generator to surface-treat an outer surface of the cylindric workpiece. In addition, the present disclosure provides a system for surface treatment of an annular workpiece, including a nozzle of a plasma generator disposed on one side of the workpiece, and a vacuum suction device disposed on the other side of the workpiece to surface-treat an inner surface of the workpiece.

A system for surface treatment of a cylindric workpiece using an atmospheric pressure plasma generator according to an embodiment of the present disclosure includes a rotary plasma generator including a nozzle from which plasma is discharged, and a body to and from which the nozzle is attached and detached, and a plasma beam guide tap attached to one side of the nozzle about a rotation axis of the nozzle, in which the plasma beam guide tap is configured to discharge a plasma beam to at least a portion of a side of the workpiece while a rotation axis of the rotary plasma generator is aligned with a central axis of the cylindric workpiece.

According to an embodiment, the plasma beam guide tap is configured such that one end of the plasma beam guide tap is attached to a position deviated from the rotation axis on the nozzle, and the other end of the plasma beam guide tap faces the rotation axis.

According to an embodiment, the other end of the plasma beam guide tap is spaced apart from the side of the cylindric workpiece and rotated about the rotation axis of the rotary plasma generator.

According to an embodiment, the nozzle includes a first opening formed on the one side of the nozzle, and the first opening is formed on the one side while having at least a predetermined angle with respect to the rotation axis.

According to an embodiment, the one end of the plasma beam guide tap is coupled to the first opening, and the nozzle is formed such that a cross sectional area of an inside of the nozzle is progressively narrowed in a direction of the first opening.

A system for surface treatment of an annular workpiece using an atmospheric pressure plasma generator according to another embodiment of the present disclosure includes a plasma generator including a nozzle from which plasma is discharged, and a body to and from which the nozzle is attached and detached, and a vacuum suction device disposed at a position opposite to the nozzle, in which the vacuum suction device is configured such that, when a plasma beam is generated from the nozzle of the plasma generator toward one end of the annular workpiece, the vacuum suction device performs vacuum suction on the other end of the annular workpiece.

According to an embodiment, the nozzle and the vacuum suction device include a measuring device for measuring an inner size of the annular workpiece.

According to an embodiment, the system further includes a controller for controlling whether or not at least one of the plasma generator and the vacuum suction device is driven based on the inner size of the annular workpiece measured by the measuring device.

According to an embodiment, the controller controls a position of at least one of the plasma generator and the vacuum suction device.

According to an embodiment, the nozzle includes a second opening formed on one side in a direction of the annular workpiece, and a cross sectional area of the second opening is smaller than a cross sectional area of a third opening formed on the one end of the annular workpiece.

According to various embodiments of the present disclosure, by radiating a plasma beam to the side of the cylindric workpiece through the plasma beam guide tap attached to the nozzle of the rotary plasma generator, it is possible to provide uniform and effective surface-treatment of the side of the cylindric workpiece.

In addition, according to various embodiments of the present disclosure, when the plasma beam is generated from the nozzle of the plasma generator toward one end of the annular workpiece by using the vacuum suction device disposed at a position opposite to the nozzle of the plasma generator, the vacuum suction on the other end of the workpiece is performed such that the plasma beam can reach a certain depth of the inner surface of the workpiece, thereby performing effective surface treatment.

The effects of the present disclosure are not limited to the effects described above, and other effects that are not mentioned above can be clearly understood by those skilled in the art based on the description of the claims.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawing.

FIG. 1 is an exemplary diagram illustrating a procedure of surface treatment and bonding of cylindric and annular workpieces according to an embodiment of the present disclosure.

FIG. 2 is a schematic diagram illustrating a system for surface treatment of a side of a cylindric workpiece using a rotary plasma generator according to an embodiment of the present disclosure.

FIG. 3 is a cross-sectional view illustrating a nozzle and a plasma beam guide tap according to an embodiment of the present disclosure.

FIG. 4 is a flowchart illustrating a method for surface treatment of a cylindric workpiece using a surface treatment system according to an embodiment of the present disclosure.

FIG. 5 is a schematic diagram illustrating a system for surface treatment of an inner surface of an annular workpiece using a plasma generator and a vacuum suction device according to an embodiment of the present disclosure.

FIG. 6 is a flowchart illustrating a method for surface treatment of an annular workpiece using a surface treatment system according to an embodiment of the present disclosure.

### DETAILED DESCRIPTION OF THE INVENTION

Hereinafter, specific details for the practice of the present disclosure will be described in detail with reference to the accompanying drawings. However, in the following description, detailed descriptions of well-known functions or configurations will be omitted when it may make the subject matter of the present disclosure rather unclear.

In the accompanying drawings, the same or corresponding elements are assigned the same reference numerals. In addition, in the following description of the embodiments, duplicate descriptions of the same or corresponding elements may be omitted. However, even if descriptions of elements are omitted, it is not intended that such elements are not included in any embodiment.

The terms used in the present disclosure will be briefly described prior to describing the disclosed embodiments in detail. The terms used herein have been selected as general terms which are widely used at present in consideration of the functions of the present disclosure, and this may be altered according to the intent of an operator skilled in the art, conventional practice, or introduction of new technology. In addition, in specific cases, the term may be arbitrarily selected by the applicant, and the meaning of the term will be described in detail in a corresponding description of the embodiments. Therefore the terms used in the present disclosure should be defined based on the meaning of the terms and the overall content of the present disclosure rather than a simple name of each of the terms.

Advantages and features of the disclosed embodiments and methods of accomplishing the same will be apparent by referring to embodiments described below in connection with the accompanying drawings. However, the present disclosure is not limited to the embodiments disclosed below, and may be implemented in various different forms, and the embodiments are merely provided to make the present disclosure complete, and to fully disclose the scope of the invention to those skilled in the art to which the present disclosure pertains.

As used herein, the singular forms “a,” “an,” and “the” are intended to include the plural forms as well, unless the context clearly indicates the singular forms. Further, the plural forms are intended to include the singular forms as well, unless the context clearly indicates the plural forms.

Further, throughout the description, when a portion is stated as “comprising (including)” an element, it intends to mean that the portion may additionally comprise (or include or have) another element, rather than excluding the same, unless specified to the contrary.

In the present disclosure, it is to be noted that the upper direction of the drawing may be referred to as “upper portion” or “upper side” of the configuration shown in the drawing, and the lower direction may be referred to as “lower portion” or “lower side”. In addition, in the drawings, a portion between the upper and lower portions of the configuration shown in the drawings, or a portion other than the upper and lower portions may be referred to as “side portion” or “side”. Relative terms such as “upper portion” and “upper side” may be used to describe the relationship between components shown in the drawings, and the present disclosure is not limited by these terms.

In the present disclosure, the statement “A and/or B” means “A”, or “B”, or “A and B”.

In the present disclosure, the term “part” or “portion” or “module” means a mechanical or hardware component, a software component, or a combination thereof, and a “unit” or “module” may be configured to perform a specific role or function. However, it does not mean that “unit” or “module” is limited to a mechanical component or hardware or software. The “unit” or “module” may be configured to be in an addressable storage medium or to execute one or more processors. Accordingly, as an example, the “unit” or “module” includes elements such as software elements, object-oriented software elements, class elements, and task elements, processes, functions, attributes, procedures, subroutines, program code segments, drivers, firmware, micro-codes, circuits, data, database, data structures, tables, arrays, and variables. Functions provided in the components and the “units” or “modules” described in the present disclosure may be combined as a smaller number of components and “units” or “modules”, or further divided into additional components and “units” or “modules”.

In the present disclosure, a “system” may mean a mechanical or electromechanical device including one or more plasma generators, a vacuum suction device, a computing device, and the like, or a device or equipment including a combination of the above, but is limited thereto.

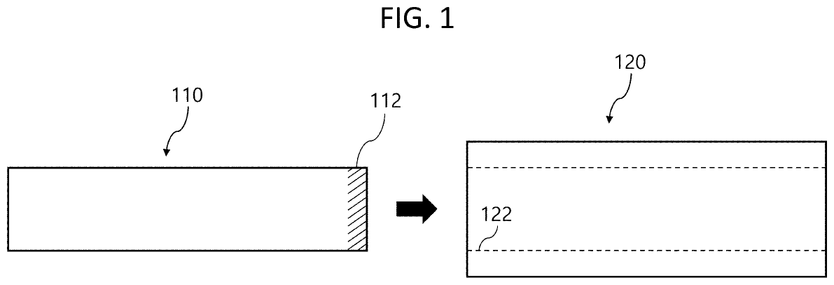

FIG. 1 is an exemplary diagram illustrating a procedure of surface treatment and bonding of a cylindric workpiece 110 and an annular workpiece 120 according to an embodiment of the present disclosure.

As illustrated, for mutual coupling and bonding of the cylindric workpiece 110 and the annular workpiece 120, in order to improve the modification or adhesion of the mutually coupled surfaces, the plasma surface treatment may be performed on a portion 112 of an outer surface of the cylindric workpiece 110 and a portion 122 of an inner surface of the annular workpiece 120.

For example, a plasma generator (not illustrated) used for such plasma-surface-treatment may discharge the generated plasma to the surfaces of the workpieces 110 and 120 formed of a polymer organic material to modify the surface of the workpieces. Through such plasma-surface-treatment, hydrophobicity, hydrophilicity, dyeability, adhesiveness, and the like of the polymer material can be improved. In another example, the plasma generator may be used for surface treatment of the workpieces 110 and 120 formed of metal, and in this case, it is possible to improve the wear resistance and corrosion resistance of the surface by coating the surface of the metal with a carbide film such as TiN/C, CrN/C, AIN, and the like.

The cylindric workpiece 110 and the annular workpiece 120 with the surface adhesiveness improved through the plasma-surface-treatment may be coupled by fitting and then bonded.

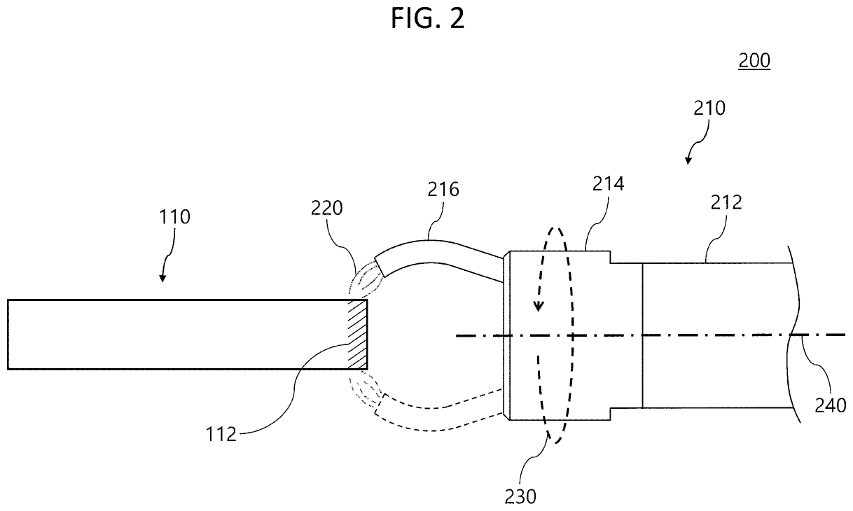

FIG. 2 is a schematic diagram illustrating a system 200 for surface treatment of a side of the cylindric workpiece 110 using a rotary plasma generator 210 according to an embodiment of the present disclosure.

As illustrated, the system 200 may include the rotary plasma generator 210 including a nozzle 214 from which plasma is discharged and a body 212 to and from which the nozzle 214 is attachable and detachable, and a plasma beam guide tap 216 attached to one side of the nozzle 214 about a rotation axis of the nozzle 214.

When the rotary plasma generator 210 is an atmospheric pressure plasma generator, the rotary plasma generator 210 may include a generator, a high voltage transformer, electrodes for generating plasma discharge, and the like, so as to be driven in a normal room temperature and normal pressure environment. In an embodiment, as illustrated in FIG. 2, the rotary plasma generator 210 may include the nozzle 214 from which plasma is discharged, a gas supply pipe (not illustrated) configured such that the nozzle 214 is attached to and detached from one side and a working gas is supplied from the other side, the body 212 to and from which a cable or the like connected to a high voltage transformer (not illustrated) is attached and detached, and a motor (not illustrated) configured to rotate the body about a rotation axis 240. The high frequency high voltage generated by the high voltage transformer is applied to the electrodes installed inside the body 212, and a high frequency discharge in the form of an electric arc may be generated between the electrodes by the applied voltage. As described above, the electric arc is generated inside the body portion 212, the working gas may contact the electric arc and be converted into the plasma state. The plasma beam generated by the body 212 may be discharged through a first opening of the nozzle 214.

The nozzle 214 of the rotary plasma generator 210 is a place where the plasma beam is discharged, and it may be integrally coupled to the rotary plasma generator 210 or may be detachably coupled thereto. In the plasma treatment process, the area, intensity, and the like of the spreading plasma beam may be adjusted according to the size, length, and shape of the nozzle 214 of the rotary plasma generator 210. For example, a thin and long nozzle may generate a plasma beam that is up to 1.5 to 2 times longer than that of a related general nozzle, and a circular nozzle may be capable of a wider surface treatment than the related general nozzle.

In an embodiment, the first opening may be formed on the one side of the nozzle 214 while having at least a predetermined angle with respect to the rotation axis 240. In this example, the first opening may correspond to the last portion of a path through which the plasma beam is discharged from inside the nozzle 214.

The plasma beam guide tap 216 may be attached to the one side of the nozzle 214 about the rotation axis 240 to guide the movement and discharge path of the plasma beam. Specifically, the plasma beam guide tap 216 may be configured such that, in a state in which the rotation axis 240 of the rotary plasma generator 210 is aligned with the central axis of the workpiece 110, the plasma beam guide tap 216 discharges a plasma beam 220 to at least the portion 112 of the side of the cylindric workpiece 110.

As illustrated in FIG. 2, the plasma beam guide tap 216 has a pipe- or arc-shape that is curved as a whole, but is not limited thereto. In another embodiment, the plasma beam guide tap 216 may include a pipe- or arc-shaped configuration that is bent with an angle at one or more positions in its longitudinal direction.

As illustrated, one end of the plasma beam guide tap 216 may be attached to a position deviated from the rotation axis 240 on the nozzle 214. In an embodiment, the one end of the plasma beam guide tap 216 may be coupled to the first opening formed on the one side of the nozzle 214. For example, the one end of the plasma beam guide tap 216 may be screw-coupled to the first opening.

In FIG. 2, it is illustrated that the one end of the plasma beam guide tab 216 is coupled to the side of the nozzle 214, but embodiments are not limited thereto. In another embodiment, the one end of the plasma beam guide tap 216 may be coupled to a lower side or the other side of the nozzle 214 rather than the side of the nozzle 214. In addition, in an embodiment, the one end of the plasma beam guide tap 216 may be detachably installed on the side of the nozzle 214 or integrally coupled to one side of the nozzle 214.

In an embodiment, the other end of the plasma beam guide tap 216 may be configured to face the cylindric workpiece 110 positioned on the rotation axis 240. In this case, the other end of the plasma beam guide tap 216 may be in the state of being spaced apart from the side of the cylindric workpiece 110 and rotated together with the workpiece 110 as the body 212 and the nozzle 214 of the rotary plasma generator 210 are rotated about the rotation axis 240.

According to the configuration of the plasma beam guide tap 216 described above, the plasma beam 220 discharged through the first opening of the nozzle 214 may be introduced through the one end of the plasma beam guide tap 216, guided along a passage formed inside the plasma beam guide tap 216, and discharged through the other end of the plasma beam guide tap 216. As illustrated, the plasma beam 220 discharged through the other end of the plasma beam guide tap 216 may be discharged to the portion 112 of the side of the cylindric workpiece 110 adjacent to the other end of the plasma beam guide tap 216. In addition, as the other end of the plasma beam guide tap 216 is rotated about the rotation axis 240, the plasma beam 220 may be discharged along a circumference of the side of the cylindric workpiece 110.

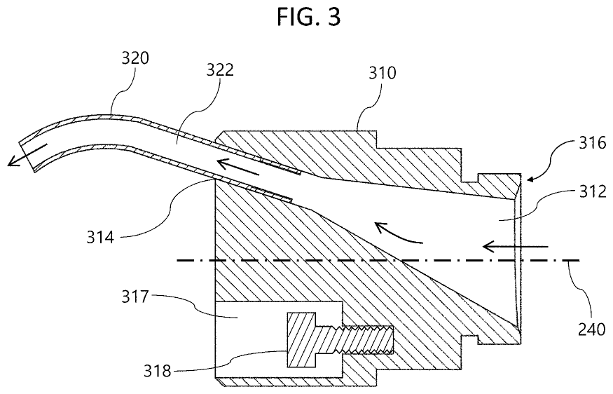

FIG. 3 is a cross-sectional view illustrating a nozzle 310 and a plasma beam guide tap 320 according to an embodiment of the present disclosure.

In FIG. 3, the illustration of the configurations corresponding to the cylindric workpiece 110, the body 212, and the like illustrated in FIG. 2 is omitted for a clearer understanding of the structure of the rotary plasma generator. The nozzle 310 and the plasma beam guide tap 320 illustrated in FIG. 3 may be used as the nozzle 214 and the plasma guide tap 216 illustrated in FIG. 2, for example.

As illustrated, the nozzle 310 may have a structure in which the rotary plasma generator (or body) is attachable to and detachable from one end 316. For example, the one end 316 of the nozzle 310 may include a structure capable of fitting or screw-coupling with the rotary plasma generator. In an embodiment, a space 312 may be formed inside the nozzle 310 to guide the movement of the plasma beam introduced from the one end 316 of the nozzle 310. A first opening 314 to be coupled with the plasma guide tap 320 may be formed on one end of the space 312. The space 312 may be formed such that its cross sectional area is progressively narrowed in a direction from the one end 316 of the nozzle 310 to the first opening 314. For example, the space 312 may have a conical shape that is narrowed in a direction from the one end 316 of the nozzle 310 to the first opening 314.

One end of the plasma guide tap 320 may be coupled to the first opening 314 formed at a position deviated from the rotation axis 240. In FIG. 3, it is illustrated that the method of coupling between the plasma guide tap 320 and the first opening 314 is an insertion coupling by force fitting or the like, but embodiments are not limited thereto. For example, the method of coupling between the plasma guide tap 320 and the first opening 314 may be a screw coupling of threads formed on inner and outer circumferential surfaces of the coupling elements of each configuration.

A passage 322 for guiding a movement and a discharge direction of the plasma beam may be formed inside the plasma guide tap 320. The plasma beam generated by the rotary plasma generator may be introduced through the one end 316 of the nozzle 310, moved along the passage 322 connected between the space 312 and the one end of the plasma guide tap 320, and then finally discharged through the other end of the plasma guide tap 320.

According to an embodiment, a counterweight space 317 having a counterweight 318 installed therein may be formed on the side on which the first opening 314 is formed, and at a position opposite to the first opening 314 with respect to the rotation axis 240 of the nozzle 310. A coupling hole may be formed on an inner side of the counterweight space 317 to receive the counterweight 318 to be coupled thereto, and one end of the counterweight 318 may be coupled to the coupling hole by screw-coupling, for example. The counterweight space 317 and the counterweight 318 may be configured such that during a rotation of the nozzle 310, the nozzle 310 maintains a weight balance between the first opening 314 and the counterweight space 317 with respect to the rotation axis 240. With this configuration, vibration or noise caused by weight imbalance generated during the rotation of the nozzle 310 can be reduced. The size of the counterweight space 317 and the position, weight and/or size of the counterweight 318 may be appropriately adjusted to maintain the weight balance with the first opening 314.

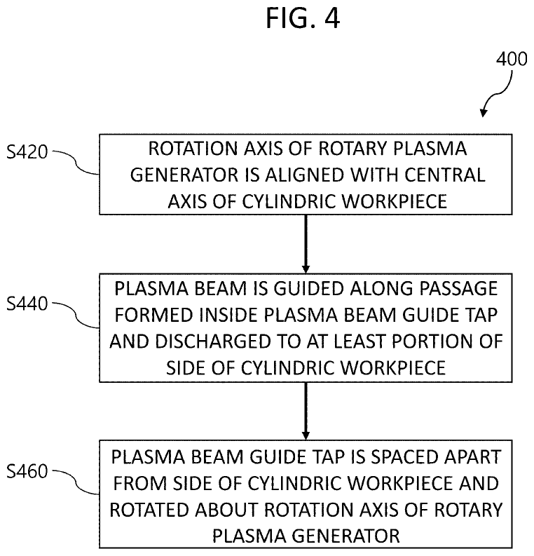

FIG. 4 is a flowchart illustrating a method for surface treatment of a cylindric workpiece using a surface treatment system according to an embodiment of the present disclosure.

The method for surface treatment of the cylindric workpiece may be initiated by aligning the rotation axis of the rotary plasma generator with the central axis of the cylindric workpiece, at S420.

Next, the plasma beam generated by the rotary plasma generator may be guided along the passage formed inside the plasma beam guide tap and discharged to at least a portion of the side of the cylindric workpiece, at S440.s

Subsequently, the plasma beam guide tap may be in the state of being spaced apart from the side of the cylindric workpiece and rotated about the rotation axis of the rotary plasma generator, at S460. Accordingly, by the plasma beam discharged from the plasma beam guide tap rotated about the rotation axis, the circumference of the side of the cylindric workpiece can be surface-treated in the circumferential direction.

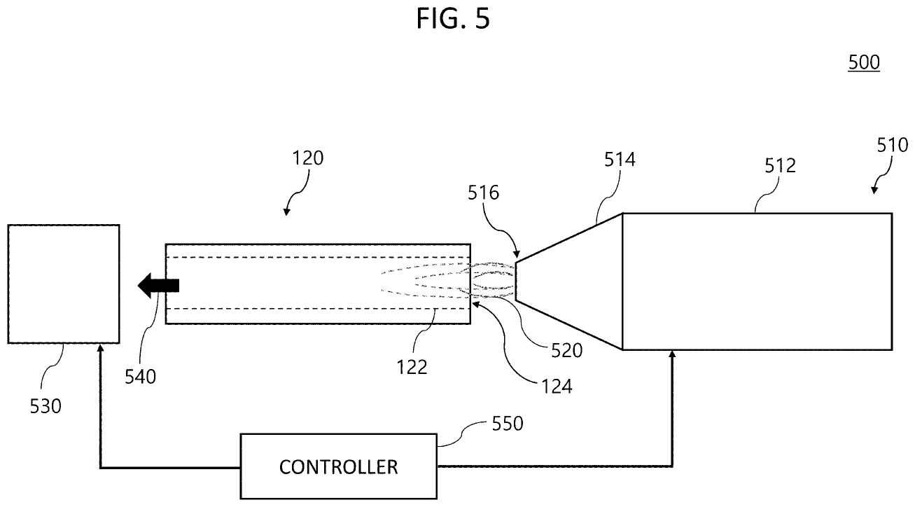

FIG. 5 is a schematic diagram illustrating a system 500 for surface treatment of the inner surface 122 of the annular workpiece 120 using a plasma generator 510 and a vacuum suction device 530 according to an embodiment of the present disclosure.

As illustrated, the system 500 may include the plasma generator 510 including a nozzle 514 from which plasma is discharged and a body 512 to and from which the nozzle 514 is attached and detached, the vacuum suction device 530 disposed at a position opposite to the nozzle 514 with respect to the workpiece 120, and a controller 550 for controlling driving and positions of the plasma generator 510 and the vacuum suction device 530.

When the plasma generator 510 is an atmospheric pressure plasma generator, the rotary plasma generator 210 may include a generator, a high voltage transformer, electrodes for generating plasma discharge, and the like, so as to be driven in a normal room temperature and normal pressure environment. In an embodiment, as illustrated in FIG. 5, the plasma generator 510 may include the nozzle 514 from which plasma is discharged, a gas supply pipe (not illustrated) configured such that the nozzle 514 is attached to and detached from one side and a working gas is supplied from the other side, and the body 212 to and from which a cable or the like connected to a high voltage transformer (not illustrated) is attached and detached. The high frequency high voltage generated by the high voltage transformer is applied to the electrodes installed inside the body 512, and a high frequency discharge in the form of an electric arc may be generated between the electrodes by the applied voltage. As described above, the electric arc is generated inside the body portion 512, and the working gas may contact the electric arc and be converted into the plasma state. The plasma beam generated in the body portion 512 may be discharged through an opening of the nozzle part 514.

The nozzle 514 of the plasma generator 510 is a place where the plasma beam is discharged, and it may be integrally coupled to the rotary plasma generator 510 or may be detachably coupled thereto. In the plasma treatment process, the area, intensity, and the like of the spreading plasma beam may be adjusted according to the size, length, and shape of the nozzle 514 of the plasma generator 510. For example, a thin and long nozzle may generate a plasma beam that is up to 1.5 to 2 times longer than that of a related general nozzle, and a circular nozzle may be capable of a wider surface treatment than the related general nozzle.

In an embodiment, a second opening 516 may be formed on one side of the nozzle 514 opposite to one end of the annular workpiece 120. In this example, the second opening 516 may correspond to the last portion of a path through which the plasma beam is discharged from inside the nozzle 514. In an embodiment, a cross sectional area of the second opening 516 may be smaller than a cross sectional area of a third opening 124 formed on one end of the annular workpiece 120 such that a plasma beam 520 is discharged to the inner surface 122 of the annular workpiece 120.

As illustrated in FIG. 5, the plasma beam 520 discharged from the nozzle 514 may reach the inner surface 122 of the annular workpiece 120 through the third opening 124 formed on the one end of the annular workpiece 120. However, depending on the shape or structure of the nozzle 514, the plasma beam 520 may not be moved far enough to reach a region requiring surface-treatment on the inner surface 122 of the annular workpiece 120. Accordingly, while the plasma beam 520 is discharged from the plasma generator 510, the vacuum suction device 530 installed on the other end of the annular workpiece 120 may be driven.

When the plasma beam 520 is generated from the nozzle 514 of the plasma generator 510 toward the one end of the annular workpiece 120, the vacuum suction device 530 may be configured to perform vacuum suction on the other end of the annular workpiece 120. In accordance with the operation of the vacuum suction device 530, the plasma beam 520 may be expanded in a direction 540 of the vacuum suction device 530 such that the plasma beam 520 may reach the inner surface 122 located deeper in the annular workpiece 120.

In an embodiment, the nozzle 514 and the vacuum suction device 530 may include a measuring device (not illustrated) for measuring the length and/or size of the inner space of the annular workpiece 120. Specifically, the measuring device may be configured to measure the length and/or size of the inner space of the annular workpiece 120 to calculate the discharging amount and size of the plasma beam 520 before the plasma beam 520 is discharged. For example, the measuring device may be a type of device that has infrared transmitter and receiver installed in the nozzle 514 and the vacuum suction device 530, respectively, and may correspond to a device capable of outputting different electrical signals according to the length or size of the measurement target, but is not limited thereto. The measuring device may transmit an electrical signal including a current value or a voltage value determined according to the inner size of the annular workpiece 120 to the controller 550.

The controller 550 may receive the electrical signal transmitted from the measuring device, and determine the discharging amount or size of the plasma beam 520 corresponding to the inner length or size of the annular workpiece 120. According to the discharging amount or size of the plasma beam 520 determined as described above, the controller 550 may control the driving time, intensity, and the like of one or more of the plasma generator 510 and the vacuum suction device 530. When the controller 550 determines that the inner size (e.g., a diameter of the cross-section of the inner space) of the annular workpiece 120 is equal to or less than a reference value based on the electrical signal of the measuring device, the controller 550 may downwardly adjust the discharge intensity of the plasma beam 520 of the plasma generator 510 or may upwardly adjust the vacuum suction intensity of the vacuum suction device 530. In addition, when the controller 550 determines that the inner size of the annular workpiece 120 is equal to or greater than the reference value based on the electrical signal of the measuring device, the controller 550 may upwardly adjust the discharge intensity of the plasma beam 520 of the plasma generator 510 or downwardly adjust the vacuum suction intensity of the vacuum suction device 530.

In an embodiment, the operation control on the plasma generator 510 and the vacuum suction device 530 by the controller 550 as described above may be sequentially executed. For example, the controller 550 may execute the operation control on the plasma generator 510, and then execute the operation control on the vacuum suction device 530, and may repeat this two-step operation controls. In another embodiment, the operation control on the plasma generator 510 and the vacuum suction device 530 by the controller 550 may be executed simultaneously in parallel. In another embodiment, the controller 550 may execute the operation control on the plasma generator 510 only, without executing the operation control on the vacuum suction device 530.

In addition, the controller 550 may control the positions of the plasma generator 510 and the vacuum suction device 530. In an embodiment, the controller 550 may control the position shift of the plasma generator 510 and the vacuum suction device 530 in the direction of the annular workpiece 120. For example, the controller 550 may shift the positions of the plasma generator 510 and the vacuum suction device 530 closer to the annular workpiece 120 such that the plasma beam 520 can reach the inner surface 122 located deeper in the annular workpiece 120. In another embodiment, the controller 550 may control the position of the plasma generator 510 on a plane perpendicular to the direction of the annular workpiece 120. For example, the controller 550 may adjust a relative position of the plasma generator 510 with respect to the annular workpiece 120 such that the plasma beam 520 is discharged only to the inside, and not to the outside of the annular workpiece 120.

In an embodiment, in order to control the positions of the plasma generator 510 and the vacuum suction device 530, the controller 550 may include an electromechanical device capable of linearly moving each of the plasma generator 510 and the vacuum suction device 530 with respect to the workpiece 120. For example, the controller 550 may include a linear motor capable of linearly moving each of the plasma generator 510 and the vacuum suction device 530 with respect to the workpiece 120.

As described above, by controlling driving and the position of the plasma generator 510 and/or the vacuum suction device 530 by the controller 550, the discharging amount, size, position, and the like of the plasma beam 520 are adjusted within appropriate ranges, so that even the region of the inner surface 122 deeper in the annular workpiece 120 can be provided with appropriate surface treatment.

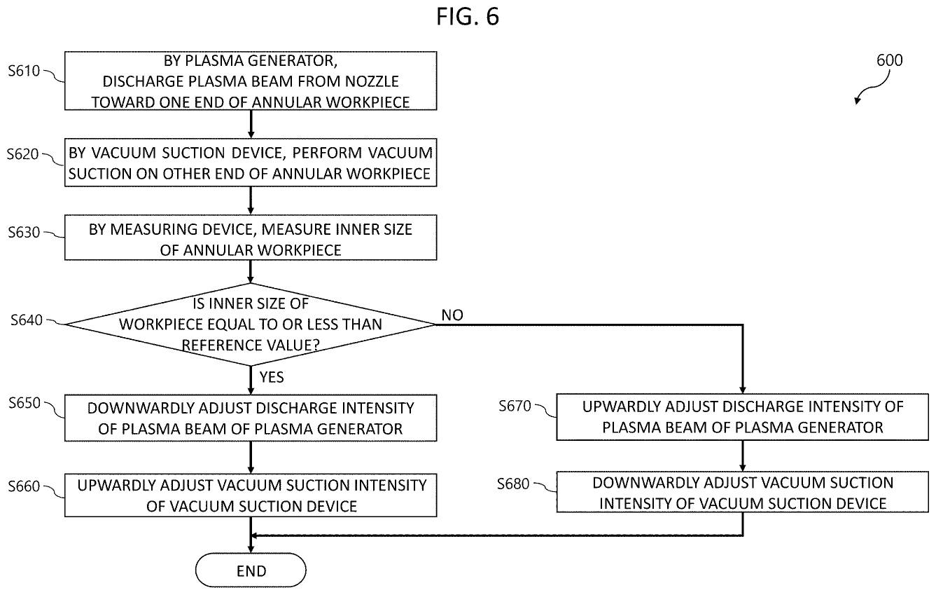

FIG. 6 is a flowchart illustrating a method for surface treatment of an annular workpiece using the surface treatment system according to an embodiment of the present disclosure.

The method for surface treatment of the annular workpiece may be started by the plasma generator discharging a plasma beam from the nozzle toward one end of the annular workpiece, at S610.

Next, the vacuum suction device may perform vacuum suction on the other end of the annular workpiece, at S620.

The inner size of the annular workpiece may be measured by the measuring device, at S630. In an embodiment, referring to FIG. 5, the measuring device (not illustrated) installed in the plasma generator 510 and the vacuum suction device 530 may measure the inner size of the annular workpiece 120. In addition, the measuring device may transmit an electrical signal determined according to the inner length or size of the annular workpiece 120 to the controller 550.

The controller may determine whether or not the inner size of the workpiece is equal to or less than the reference value, at S640. In an embodiment, referring to FIG. 5, the controller 550 may determine whether or not the inner size of the annular workpiece 120 is equal to or less than the reference value based on the electrical signal of the measuring device.

When it is determined that the size of the workpiece measured in step S640 is equal to or less than the reference value, the controller may downwardly adjust the discharge intensity of the plasma beam of the plasma generator, at S650. Then, the controller may upwardly adjust the vacuum suction intensity of the vacuum suction device, at S660. As described above, by allowing the plasma beam to be discharged deeper into the annular workpiece by the plasma generator and the vacuum suction device, even the inner surface deeper in the annular workpiece can be provided with the appropriate surface treatment.

Meanwhile, when it is determined that the size of the workpiece measured in step S640 exceeds the reference value, the controller may upwardly adjust the plasma beam discharge intensity of the plasma generator, at S670. Then, the controller may downwardly adjust the vacuum suction intensity of the vacuum suction device, at S680. As described above, the plasma generator and the vacuum suction device enable the plasma beam to be widely discharged to the inside of the annular workpiece, such that the inner surface of the annular workpiece can be provided with the appropriate surface treatment.

The preferred embodiments of the present invention described above are disclosed for purposes of illustration, and those skilled in the art with ordinary knowledge of the present invention will be able to make various modifications, changes and additions within the spirit and scope of the present invention, and such modifications, changes and additions should be construed to be included in a scope of the claims.

It should be understood that those of ordinary skill in the art to which the present disclosure pertains can make various substitutions, modifications and changes without departing from the technical spirit of the present disclosure, and thus, the present disclosure is not limited by the embodiments described above and the accompanying drawings.

1. A system for surface treatment of a cylindric workpiece using an atmospheric pressure plasma generator, comprising:
a rotary plasma generator including a nozzle from which plasma is discharged, and a body to and from which the nozzle is attached and detached; and
a plasma beam guide tap attached to one side of the nozzle about a rotation axis of the nozzle,
wherein the plasma beam guide tap is configured to discharge a plasma beam to at least a portion of a side of the workpiece while a rotation axis of the rotary plasma generator is aligned with a central axis of the cylindric workpiece.

2. The system according to claim 1, wherein the plasma beam guide tap is configured such that one end of the plasma beam guide tap is attached to a position deviated from the rotation axis on the nozzle, and
the other end of the plasma beam guide tap faces the rotation axis.

3. The system according to claim 2, wherein the other end of the plasma beam guide tap is spaced apart from the side of the cylindric workpiece and rotated about the rotation axis of the rotary plasma generator.

4. The system according to claim 2, wherein the nozzle includes a first opening formed on the one side of the nozzle, and
the first opening is formed on the one side while having at least a predetermined angle with respect to the rotation axis.

5. The system according to claim 4, wherein the one end of the plasma beam guide tap is coupled to the first opening, and
the nozzle is formed such that a cross sectional area of an inside of the nozzle is progressively narrowed in a direction of the first opening.

6. A system for surface treatment of an annular workpiece using an atmospheric pressure plasma generator, comprising:
a plasma generator including a nozzle from which plasma is discharged, and a body to and from which the nozzle is attached and detached; and
a vacuum suction device disposed at a position opposite to the nozzle,
wherein the vacuum suction device is configured such that, when a plasma beam is generated from the nozzle of the plasma generator toward one end of the annular workpiece, the vacuum suction device performs vacuum suction on the other end of the annular workpiece.

7. The system according to claim 6, wherein the nozzle and the vacuum suction device include a measuring device for measuring an inner size of the annular workpiece.

8. The system according to claim 7, further comprising a controller for controlling whether or not at least one of the plasma generator and the vacuum suction device is driven, based on the inner size of the annular workpiece measured by the measuring device.

9. The system according to claim 8, wherein the controller controls a position of at least one of the plasma generator and the vacuum suction device.

10. The system according to claim 6, wherein the nozzle includes a second opening formed on one side in a direction of the annular workpiece, and
a cross sectional area of the second opening is smaller than a cross sectional area of a third opening formed on the one end of the annular workpiece.
